(19) United States
(12) Patent Application Publication
(10) Pub. No.: US 2026/0182321 A1
(43) Pub. Date: Jun. 25, 2026

(54) METHOD FOR MANUFACTURING MEMORY DEVICE

(71) Applicant: SK hynix Inc., Gyeonggi-do (KR)

(72) Inventor: Heon Yong CHANG, Gyeonggi-do (KR)

(21) Appl. No.: 19/188,018

(22) Filed: Apr. 24, 2025

(30) Foreign Application Priority Data
Dec. 23, 2024 (KR) 10-2024-0193591

(51) Int. Cl. H01L 21/768; H01L 21/18

(52) U.S. Cl. CPC H10W 20/023; H10P 10/12

(57) ABSTRACT

A method for manufacturing a memory device, according to embodiments of the present disclosure, may comprise bonding a second semiconductor structure on a first semiconductor structure, wherein the second semiconductor structure includes a second bonding insulation layer and a bit line on the second bonding insulation layer, wherein the first semiconductor structure includes a substrate, lower lines on the substrate, and a first bonding insulation layer on the lower lines, forming a first hole exposing an upper surface of the bit line in the second semiconductor structure, and forming a second hole passing through the first bonding insulation layer and the second bonding insulation layer to expose an upper surface of the lower lines.

### CROSS-REFERENCES TO RELATED APPLICATION

The present application claims priority under 35 U.S.C. 119(a) to Korean patent application number 10-2024-0193591 filed on Dec. 23, 2024, which is incorporated herein by reference in its entirety.

### TECHNICAL FIELD

Embodiments of the present disclosure relate generally to semiconductor technology and, more particularly, to a method for manufacturing a memory device.

### BACKGROUND

Memory devices because of their miniaturization, multi-functionality, and/or low manufacturing cost characteristics are attracting attention as an important element in the electronics industry. As the electronics industry progresses, memory devices are becoming more highly integrated. However, with higher integration, the width of the lines included in the memory device is decreasing, making aligning the lines in the memory device more challenging.

### SUMMARY

Embodiments of the present disclosure may provide a method for manufacturing a memory device capable of preventing misalignment between lines.

Advantages of the embodiments of the present disclosure are not limited to those set forth herein, and other unmentioned advantages would be apparent to one of ordinary skill in the art from the following description.

Embodiments of the present disclosure provide a method for manufacturing a memory device, the method comprising bonding a second semiconductor structure on a first semiconductor structure, wherein the second semiconductor structure includes a second bonding insulation layer and a bit line on the second bonding insulation layer, wherein the first semiconductor structure includes a substrate, lower lines on the substrate, and a first bonding insulation layer on the lower lines, forming a first hole exposing an upper surface of the bit line in the second semiconductor structure, and forming a second hole passing through the first bonding insulation layer and the second bonding insulation layer to expose an upper surface of the lower lines.

Embodiments of the present disclosure provide a method for manufacturing a memory device, the method comprising bonding a second semiconductor structure, including a second bonding insulation layer and a bit line on the second bonding insulation layer, on a first semiconductor structure including a substrate, lower lines on the substrate, and a first bonding insulation layer on the lower lines, forming a first hole exposing an upper surface of the bit line in the second semiconductor structure, and forming a second hole exposing an upper surface of the lower lines and having a longer length than a length of the first hole in a direction perpendicular to an upper surface of the substrate.

According to embodiments of the present disclosure, a method for manufacturing a memory device is provided that is capable of preventing misalignment between lines.

The features, effects, and advantages of the embodiments are not limited to the foregoing advantages, and other features, effects, and advantages will become apparent to those of ordinary skill in the art from the detailed description of embodiments in conjunction with the following drawings.

### BRIEF DESCRIPTION OF THE DRAWINGS

The embodiments of the present disclosure will be more fully understood from the following detailed description and the accompanying drawings, which are provided for illustration only and are not intended to limit the embodiments.

FIG. 1 is a simplified schematic illustrating a cross-sectional structure of a memory device according to embodiments of the present disclosure.

FIGS. 2 to 11 are simplified schematics illustrating a method for manufacturing a memory device according to embodiments of the present disclosure.

FIGS. 12 and 13 are simplified schematics illustrating another method for manufacturing a memory device according to embodiments of the present disclosure.

### DETAILED DESCRIPTION

Hereinafter, embodiments of the present disclosure are described in detail with reference to the accompanying drawings. In assigning reference numerals to components of each drawing, the same components may be assigned the same numerals even when they are shown on different drawings. In instances where including detailed descriptions of known art or functions may obscure the clarity of the present disclosure, such details may be omitted, provided that the omission does not detract from the understanding of the claimed invention.

It will be further understood that the terms “comprises,” “comprising,” “includes,” and “including” when used in this specification, specify the presence of the stated elements and do not preclude the presence or addition of one or more other elements. As used herein, the term “and/or” includes any and all combinations of one or more of the associated listed items.

As used herein, the singular forms “a”, “an” and “the” are intended to include the plural forms as well, unless the context clearly indicates otherwise.

Labels as “first,” “second,” “A,” “B,” “(a),” and “(b),” may be used in describing the components of the embodiments. These labels are provided merely to distinguish a component from another, and the essence, order, or number of the components are not limited by the labels.

In describing the positional relationship between components, when two or more components are described as “connected”, “coupled” or “linked”, the two or more components may be directly “connected”, “coupled” or “linked””, or another component may intervene. Here, the other component may be included in one or more of the two or more components that are “connected”, “coupled” or “linked” to each other.

When such terms as, e.g., “after”, “next to”, “after”, and “before”, are used to describe the temporal flow relationship related to components, operation methods, and fabricating methods, it may include a non-continuous relationship unless the term “immediately” or “directly” is used.

When a component is designated with a value or its corresponding information (e.g., level), the value or the corresponding information may be interpreted as including a tolerance that may arise due to various factors (e.g., process factors, internal or external impacts, or noise).

In the accompanying drawings, the directions of the upper surface of the substrate are defined as a first direction FD and a second direction SD, respectively, and the direction protruding vertically from the upper surface of the substrate is defined as a third direction VD. The first direction FD and the second direction SD may be substantially perpendicular to each other. The third direction VD is a direction perpendicular to the first direction FD and the second direction SD. In the following specification, ‘vertical’ or ‘vertical direction’ will be used as having the same or substantially the same meaning as the third direction VD. The direction indicated by arrow in the drawings and the opposite direction indicate the same direction.

Hereinafter, various embodiments of the present disclosure will be described in detail with reference to accompanying drawings.

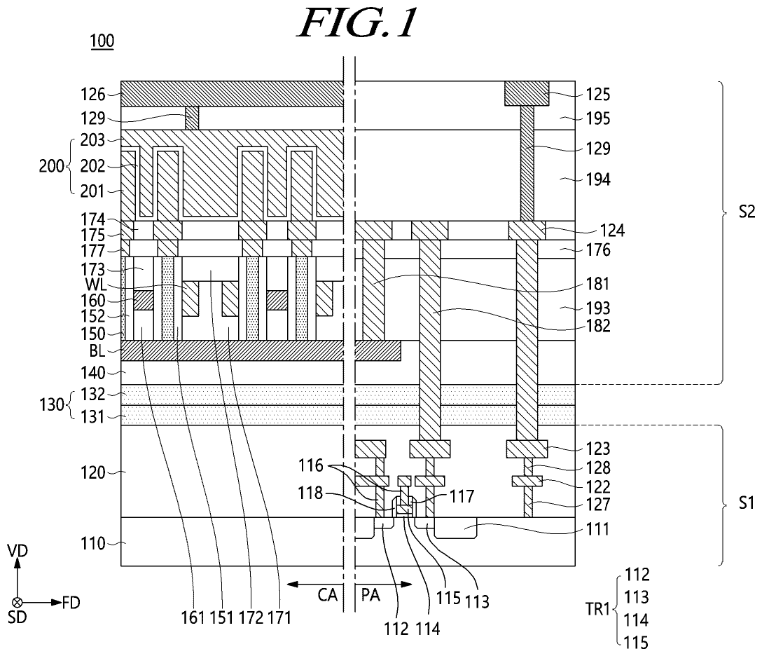

FIG. 1 is a simplified schematic illustrating a cross-sectional structure of a memory device according to embodiments of the present disclosure.

Referring to FIG. 1, a memory device according to embodiments of the present disclosure includes a first semiconductor structure S1, a second semiconductor structure S2, a bonding insulation layer 130, and a second contact plug 182.

The first semiconductor structure S1 includes a substrate 110, an element isolation layer 111, a lower transistor TR1, a gate capping layer 117, a spacer 118, a first insulation layer 120, lines 122 and 123, and contacts 116, 127, and 128.

The second semiconductor structure S2 includes a second insulation layer 140, a bit line BL, a first contact plug 181, a fourth contact 177, an interlayer insulation layer 176, a channel structure 150, a second gate insulation layer 151, a third gate insulation layer 152, a back gate electrode 160, a back gate capping layer 161, a first insulation pattern 171, a second insulation pattern 172, a third insulation pattern 173, a fourth insulation pattern 174, a word line WL, a landing pad 175, lines 124, 125, and 126, a fifth contact 129, a third insulation layer 193, a fourth insulation layer 194, a fifth insulation layer 195, and a capacitor 200.

The bonding insulation layer 130 includes a first bonding insulation layer 131 and a second bonding insulation layer 132.

The lower transistor TR1 includes a source area 112, a drain area 113, a first gate insulation layer 114, and a gate electrode layer 115. The capacitor 200 includes a lower electrode 201, a dielectric layer 202, and an upper electrode 203.

The substrate 110 includes a cell area CA and a peripheral area PA. A memory cell is disposed in the cell area CA. Peripheral circuits for transferring various voltages or signals to the memory cell are disposed in the peripheral area PA. The peripheral area PA is disposed around the cell area CA. In an embodiment, the peripheral area PA may surround the cell area CA.

The substrate 110 may include a semiconductor substrate such as a silicon wafer or a silicon on insulator (SOI) wafer. The substrate 110 may include a group III-V semiconductor substrate, e.g., a compound semiconductor substrate such as GaAs. The substrate 110 may include monocrystalline silicon, polysilicon, amorphous silicon, monocrystalline silicon germanium, polycrystalline silicon germanium, carbon-doped silicon, or a combination thereof.

At least one element isolation layer 111 is disposed in the substrate 110. The element isolation layer 111 may be formed using a trench element isolation technology such as shallow trench isolation (STI). The element isolation layer 111 may include silicon oxide, silicon nitride, silicon oxynitride, low-K dielectrics, high-K dielectrics, or a combination thereof.

In the peripheral area PA, the lower transistor TR1 is disposed on the substrate 110. In an embodiment, the lower transistor TR1 may be any of the transistors included in the peripheral circuit. The first contact 116 is connected to the source area 112 and the drain area 113 of the lower transistor TR1 formed in the substrate 110. The second contact 127, the first line 122, the third contact 128, and the second line 123 may be sequentially disposed on the substrate 110 in an area other than the area in which the lower transistor TR1 is disposed. The first line 122 may be connected to the first contact 116 and the second contact 127. The second line 123 may be connected to the third contact 128. The first insulation layer 120 is disposed to cover the lower transistor TR1, the first contact 116, the second contact 127, the first line 122, the third contact 128, and the second line 123.

The second line 123 may be referred to as a lower line. The second line 123 may be connected to the drain area 113 of the lower transistor TR1 through the first contact 116, the first line 122, and the third contact 128.

The first bonding insulation layer 131 is disposed on the first semiconductor structure S1. The first bonding insulation layer 131 is disposed between the first semiconductor structure S1 and the second semiconductor structure S2. The second bonding insulation layer 132 is disposed under the second semiconductor structure S2. The second bonding insulation layer 132 is disposed between the first bonding insulation layer 131 and the second semiconductor structure S2.

The first gate insulation layer 114 and the first insulation layer 120 may include silicon oxide, silicon nitride, silicon oxynitride, high-K dielectric, or a combination thereof. The gate electrode 115, the first contact 116, the second contact 127, the first line 122, the third contact 128, and the second line 123 may include a conductive material such as metal, metal oxide, metal nitride, metal silicide, polysilicon, conductive carbon, or a combination thereof. The bonding insulation layer 130 may include silicon oxide, silicon nitride, silicon oxynitride, silicon carbonitride, high-K dielectric, or a combination thereof.

A second semiconductor structure S2 is disposed on the second bonding insulation layer 132. The second semiconductor structure S2 may be bonded to the first semiconductor structure S1 through a bonding insulation layer 130.

The second insulation layer 140 is disposed on the second bonding insulation layer 132. A bit line BL is disposed on the second insulation layer 140. The bit line BL extends along the first direction FD. The second insulation layer 140 may include silicon oxide, silicon nitride, silicon oxynitride, silicon carbonitride, high-K dielectric, or a combination. The bit line BL may include a conductive material such as metal, metal nitride, metal silicide, polysilicon, conductive carbon, or a combination thereof.

A memory cell is disposed on the bit line BL in the cell area CA. In an embodiment, the memory cell may include one transistor and one capacitor. Hereinafter, an embodiment in which the memory cell includes one transistor and one capacitor is described.

The channel structure 150 contacts the upper surface of the bit line BL and extends in the vertical direction. The channel structure 150 may include a channel area formed in an area overlapping the word line WL in the first direction FD. The channel structure 150 may include a source or drain area formed above or below the channel area. For example, the source area may be formed above the channel area in the channel structure 150, and the drain area may be formed below the channel area in the channel structure 150. The channel structure 150 may include polysilicon or single crystalline silicon.

A second gate insulation layer 151 and a third gate insulation layer 152 are disposed on a side surface of the channel structure 150. The second gate insulation layer 151 is disposed between the channel structure 150 and the word line WL. The second gate insulation layer 151 extends in a vertical direction. The third gate insulation layer 152 is disposed between the channel structure 150 and the back gate electrode 160. The third gate insulation layer 152 extends in a vertical direction. The second gate insulation layer 151 and the third gate insulation layer 152 may include silicon oxide, silicon nitride, silicon oxynitride, silicon carbonitride, a high-K dielectric, or a combination thereof.

The word line WL, the first insulation pattern 171, and the second insulation pattern 172 are disposed between the second gate insulation layers 151 facing each other. The length of the word line WL in the vertical direction may be shorter than the length of the channel structure 150 in the vertical direction. The first insulation pattern 171 is positioned between the word lines WL facing each other. The first insulation pattern 171 may cover one side surface and a lower surface of the word line WL. The second insulation pattern 172 may cover an upper surface of the first insulation pattern 171 and the word line WL.

The back gate electrode 160, the second gate capping layer 161, and the third insulation pattern 173 are disposed between the third gate insulation layers 152 facing each other. The length of the back gate electrode 160 in the vertical direction may be shorter than the length of the channel structure 150 in the vertical direction. The second gate capping layer 161 is disposed between the back gate electrode 160 and the bit line BL. The third insulation pattern 173 is disposed on the back gate electrode 160. The second gate capping layer 161, the back gate electrode 160, and the third insulation pattern 173 overlap each other in the vertical direction.

The word line WL and the back gate electrode 160 may include a conductive material such as metal, metal nitride, metal silicide, polysilicon, conductive carbon, or a combination thereof. The first insulation pattern 171, the second insulation pattern 172, the third insulation pattern 173, the fourth insulation pattern 174, and the second gate capping layer 161 may include silicon oxide, silicon nitride, silicon oxynitride, silicon carbonitride, high-K dielectric, or a combination thereof.

In the cell area CA, a fourth contact 177 and an interlayer insulation layer 176 are disposed on the channel structure 150, the second gate insulation layer 151, the third gate insulation layer 152, the second insulation pattern 172, and the third insulation pattern 173. The fourth contact 177 may be disposed to correspond to one channel structure 150.

A fourth insulation pattern 174 and a landing pad 175 are disposed on the fourth contact 177 and the interlayer insulation layer 176. The landing pad 175 may be positioned to correspond to one fourth contact 177. The landing pad 175 contacts the upper surface of the corresponding fourth contact 177. The fourth insulation pattern 174 is disposed between the landing pads 175.

The fourth contact 177 and the landing pad 175 may include a conductive material such as metal, metal nitride, metal silicide, polysilicon, conductive carbon, or a combination thereof. The interlayer insulation layer 176 and the fourth insulation pattern 174 and the interlayer insulation layer 174 may include silicon oxide, silicon nitride, silicon oxynitride, silicon carbonitride, a high-K dielectric, or a combination thereof.

A first contact plug 181 is disposed on the bit line BL in the peripheral area PA. One side of the first contact plug 181 contacts the upper surface of the bit line BL and extends in the vertical direction. The third line 124 and the fourth insulation pattern 174 may be disposed on the bit line connection contact 181. The third line 124 may be referred to as an upper line. The other side of the first contact plug 181 contacts the third line 124.

The first contact plug 182 is disposed on the second line 123. One side of the second contact plug 182 contacts the upper surface of the second line 123. The other side of the second contact plug 182 is connected to the third line 124. The second contact plug 182 extends in a vertical direction from the upper surface of the second line 123, may pass through the bonding insulation layer 130, the first insulation layer 140, the third insulation layer 193, and the interlayer insulation layer 176, and contacts the lower surface of the third line 124.

The bit line BL may be connected to the second line 123 through the first contact plug 181, the third line 124, and the second contact plug 182. The second line 123 may be connected to the lower transistor TR1 through the third contact 128, the first line 122, and the first contact 116.

The first contact plug 181, the third line 124, and the second contact plug 182 may include a conductive material such as metal, metal oxide, metal nitride, metal silicide, polysilicon, conductive carbon, or a combination thereof. The third line 124 may be referred to as an upper line.

The capacitor 200 is disposed on the fourth insulation pattern 174 and the landing pad 175. The lower electrode 201 of the capacitor 200 may correspond to one landing pad 175. The lower electrode 201 contacts the upper surface of the landing pad 175. The dielectric layer 202 is disposed to cover the side surface and the upper surface of the lower electrode 201, and the upper surface of the fourth insulation pattern 174. In an embodiment, the dielectric layer 202 may conformally cover the side surface and the upper surface of the lower electrode 201. The upper electrode 203 is disposed on the dielectric layer 202. The lower electrode 201 and the upper electrode 203 may include a conductive material such as metal, metal oxide, metal nitride, metal silicide, polysilicon, conductive carbon, or a combination thereof. The dielectric layer 202 may include a high dielectric material, silicon oxide, silicon nitride, or a combination thereof.

A fifth contact 129 and a fifth insulation layer 195 are disposed on the upper electrode 203. A sixth line 126 is disposed on the fifth contact 129 and the fifth insulation layer 195.

The fourth insulation layer 194 and the fifth contact 129 are disposed on the third line 124 and the fourth insulation pattern 174. The fifth contact 129 may penetrate the fourth insulation layer 194 to contact the upper surface of at least one third line 124. The fifth insulation layer 195 is disposed on the fourth insulation layer 194. The fifth line 125 is disposed in the fifth insulation layer 195.

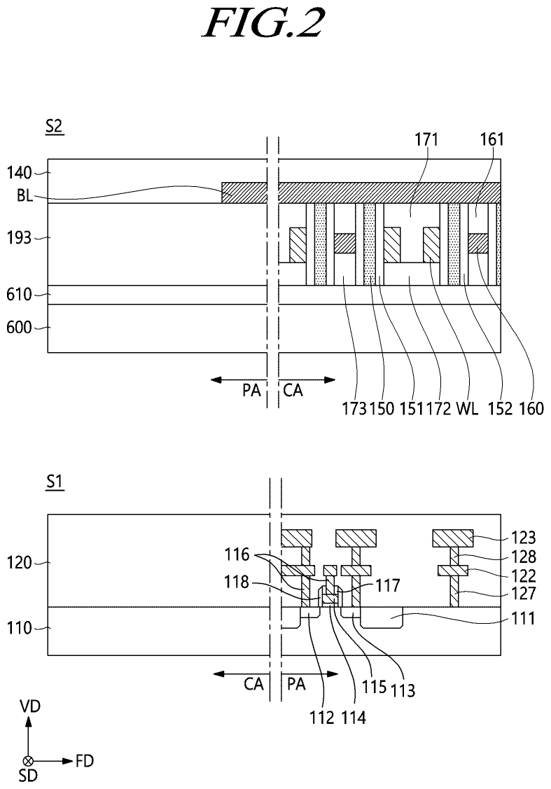

FIGS. 2 to 11 are simplified schematics illustrating a method for manufacturing a memory device according to embodiments of the present disclosure.

Referring to FIG. 2, a second semiconductor structure S2 is prepared. The second semiconductor structure S2 includes the first substrate 600, the sixth insulation layer 610, the third insulation layer 193, the channel structure 150, the second gate insulation layer 151, the third gate insulation layer 152, the word line WL, the back gate electrode 160, the second gate capping layer 161, the first insulation pattern 171, the second insulation pattern 172, the third insulation pattern 173, the bit line BL, and the second insulation layer 140. The second insulation pattern 140 may be disposed on the third insulation layer 193 and the bit line BL. The sixth insulation layer 610 may be formed on the first substrate 600. The third insulation layer 193 may be formed on the sixth insulation layer 610. The channel structure 150, the second gate insulation layer 151, the third gate insulation layer 152, the word line WL, the back gate electrode 160, the second gate capping layer 161, the first insulation pattern 171, the second insulation pattern 172 and the third insulation pattern 173 may be disposed on the sixth insulation layer 610.

The first semiconductor structure S1 may be prepared to include the substrate 110, the element isolation layer 111, the first insulation layer 120, the source area 112, the drain area 113, the first gate insulation layer 114, the gate electrode layer 115, the gate capping layer 117, the spacer 118, the first contact 116, the second contact 127, the first line 122, the third contact 128, and the second line 123. The first insulation layer 120 may be disposed on the substrate 110.

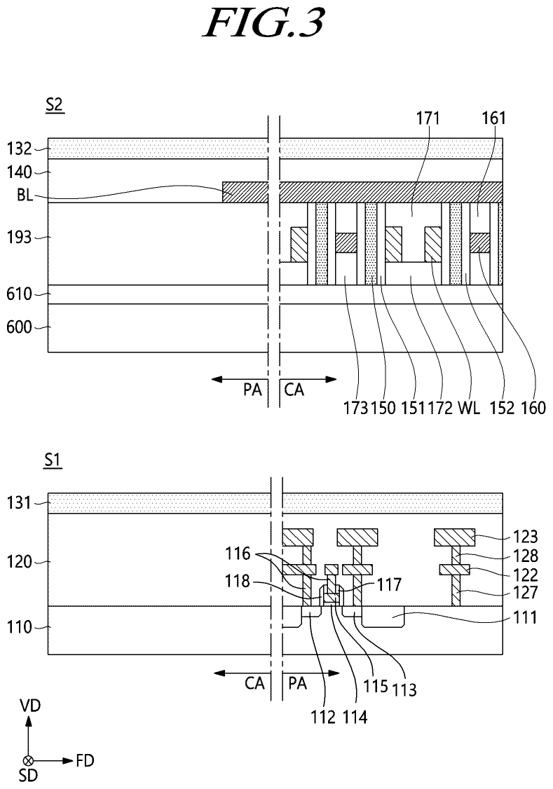

Referring to FIG. 3, a second bonding insulation layer 132 may be formed on the second insulation layer 140. The first bonding insulation layer 131 may be formed on the first insulation layer 120. The first bonding insulation layer 131 may include the same material as the material forming the second bonding insulation layer 132. In an embodiment, the first and second bonding insulation layers 131 and 132 may include silicon carbonitride.

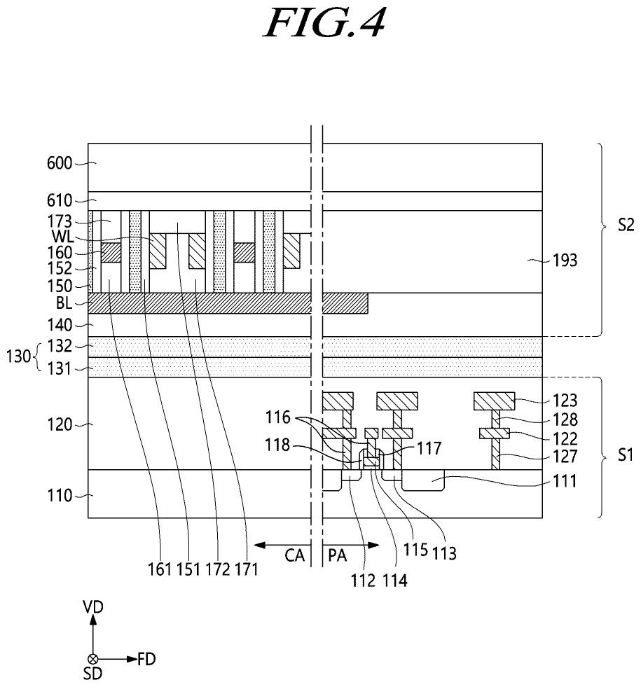

Referring to FIG. 4, the second bonding insulation layer 132 may be bonded on the first bonding insulation layer 131. In an embodiment, the process of bonding the first and second semiconductor structures S1 and S2 may include a process of applying heat after bringing the second bonding insulation layer 132 of the second semiconductor structure S2 in contact with the first bonding insulation layer 131 of the first semiconductor structure S1. As illustrated in the FIG. 4, the second semiconductor structure S2 may be positioned on top of the first semiconductor structure S1 and a lower surface of the second bonding insulation layer 132 may be bonded with an upper surface of the first bonding insulation layer 131. However, it should be noted that the direction of the stacking of the first and second semiconductor structures may be reversed without departing from the technical concepts of the invention.

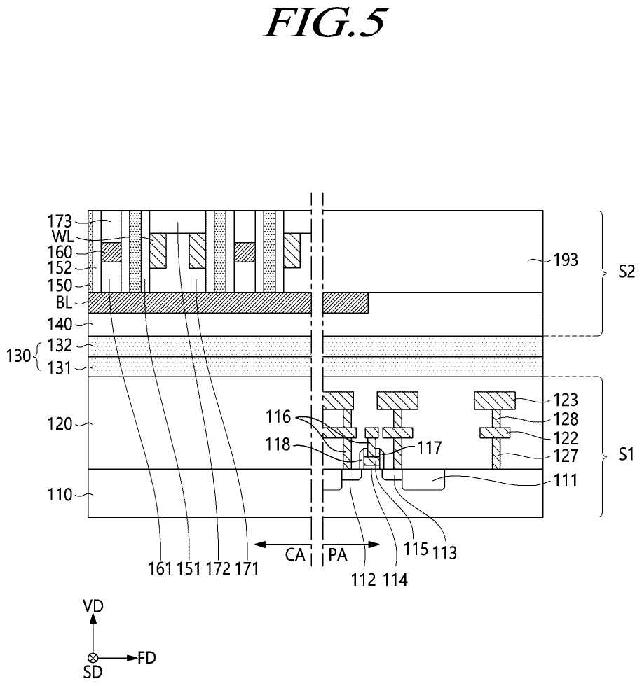

Referring to FIG. 5, the first substrate 600 and the sixth insulation layer 610 may be removed. In an embodiment, the first substrate 600 may be removed through a grinding process or a chemical mechanical polishing (CMP) process. In an embodiment, the sixth insulation layer 610 may be removed by a wet etching process.

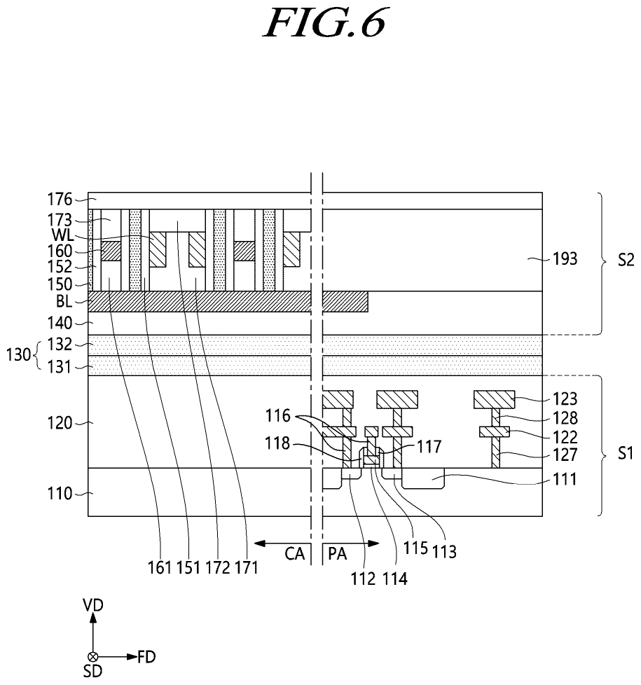

Referring to FIG. 6, an interlayer insulation layer 176 may be formed on the third insulation layer 193, the second insulation pattern 172, the third insulation pattern 173, the second gate insulation layer 151, the third gate insulation layer 152, and the channel structure 150. In an embodiment, the interlayer insulation layer 176 may include nitride.

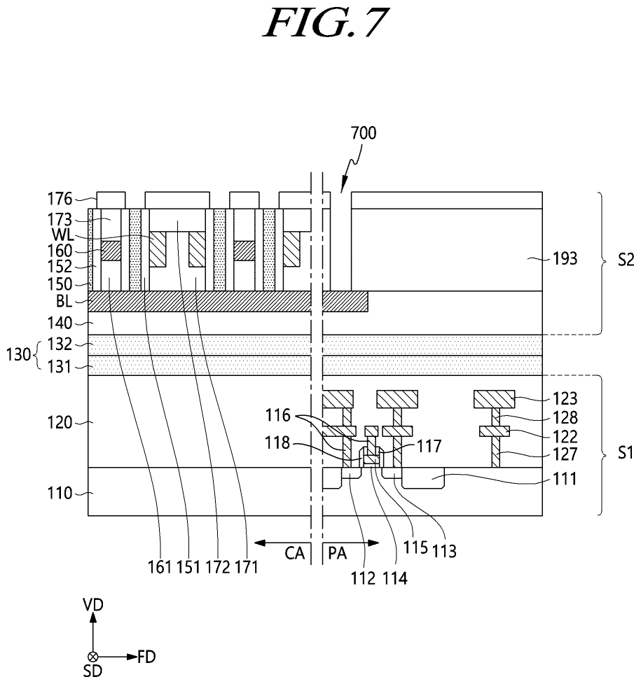

Referring to FIG. 7, a first through hole 700 may be formed exposing the upper surface of the bit line BL.

The process of forming the first through hole 700 includes an etching process. The etching process may include, e.g., a dry etching process. The process of forming the first through hole 700 may include a process of etching oxide and nitride. When the first through hole 700 is formed, a portion of the interlayer insulation layer 176 overlapping the channel structure 150 may be removed together. The first through hole 700 may pass through the interlayer insulation layer 176 and the third insulation layer 193 in the vertical direction to expose the upper surface of the bit line BL.

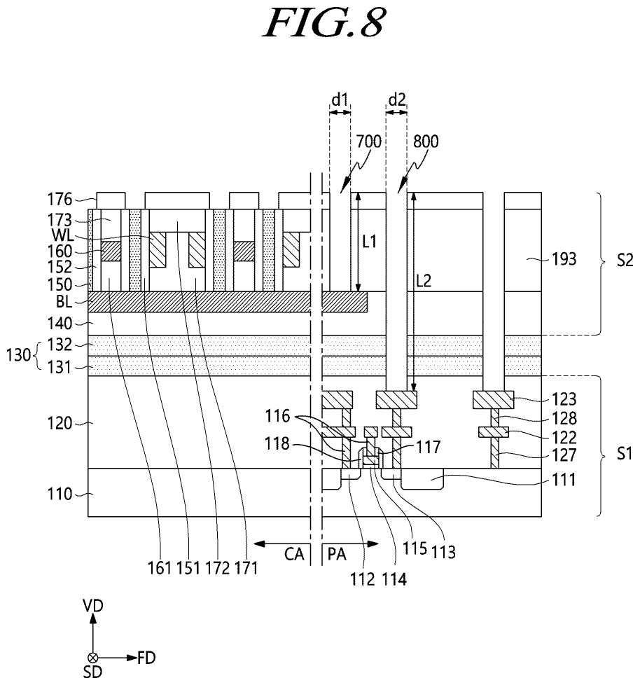

Referring to FIG. 8, a second through hole 800 may be formed to expose an upper surface of the second line 123.

The process of forming the second through hole 800 may be separated from the process of forming the first through hole 700. In an embodiment, the process of forming the second through hole 800 may be performed after the process of forming the first through hole 700.

The process of forming the second through hole 800 includes an etching process. The etching process may include, e.g., a dry etching process. The process of forming the second through hole 800 may include a process of etching oxide and nitride. The second through hole 800 may pass through the interlayer insulation layer 176, the third insulation layer 193, the second insulation layer 140, the bonding insulation layer 130, and the first insulation layer 120 in the vertical direction to expose the upper surface of the second line 123.

The first through hole 700 and the second through hole 800 may be formed using different etching masks. For example, the etching mask for forming the first through hole 700 may be a mask that does not expose an area where the second line 123 is positioned. Alternatively, the etching mask for forming the second through hole 800 may be a mask that does not expose an area where the bit line BL is positioned.

When the first through hole 700 and the second through hole 800 are formed, the etching mask for forming the first through hole 700 may be aligned through a different reference from the etching mask for forming the second through hole 800. For example, the etching mask for forming the first through hole 700 may be aligned with respect to the area where the bit line BL is positioned. The etching masks for forming the second through hole 800 may be aligned with respect to the area where the second line 123 is positioned.

The vertical length L1 of the first through hole 700 is shorter than the vertical length L2 of the second through hole 800. In an embodiment, the width d1 (or diameter or cross-sectional area) of the first through hole 700 may be the same or substantially the same as the width d2 (or diameter or cross-sectional area) of the second through hole 800. Alternatively, in another embodiment, the width d1 of the first through hole 700 may be thinner than the width d2 of the second through hole 800.

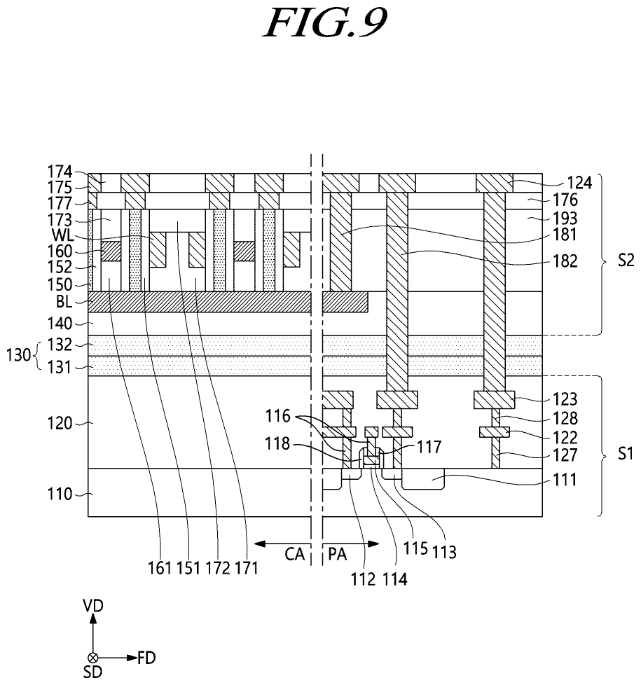

Referring to FIGS. 8 and 9, the first contact plug 181 and the second contact plug 182 are formed by filling the first through hole 700 and the second through hole 800 with a conductive material. The lower surface of the first contact plug 181 contacts the upper surface of the bit line BL. The lower surface of the second contact plug 182 contacts the upper surface of the second line 123. The upper surface of the first contact plug 181 may form the same or substantially the same plane as the upper surface of the second contact plug 182. The upper surface of the first contact plug 181 and the upper surface of the second contact plug 182 are coplanar or substantially coplanar. The first contact plug 181 may include the same material as the material forming the second contact plug 182.

A fourth contact 177 may be formed in the area where the interlayer insulation layer 176 is removed from the cell area CA. The landing pad 175 and the fourth insulation pattern 174 are formed on the fourth contact 177 and the interlayer insulation layer 176. One landing pad 175 may be formed to correspond to one fourth contact 177. A third line 124 and a fourth insulation pattern 174 are formed on the first contact plug 181, the second contact plug 182, and the third insulation layer 193 in the peripheral area PA.

The first contact plug 181 and the second contact plug 182 each are connected to the third line 124. In an embodiment, the third line 124 connected to the first contact plug 181 may be different from the third line 124 connected to the second contact plug 182.

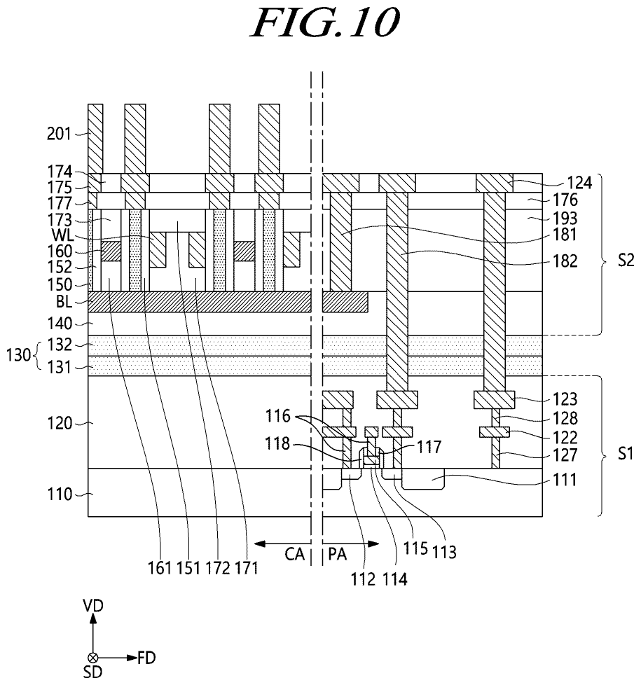

Referring to FIG. 10, the lower electrode 201 may be formed on the landing pad 175. The lower electrode 201 may be formed on the upper surface of one corresponding landing pad 175. The lower surface of the lower electrode 201 contacts the upper surface of the landing pad 175.

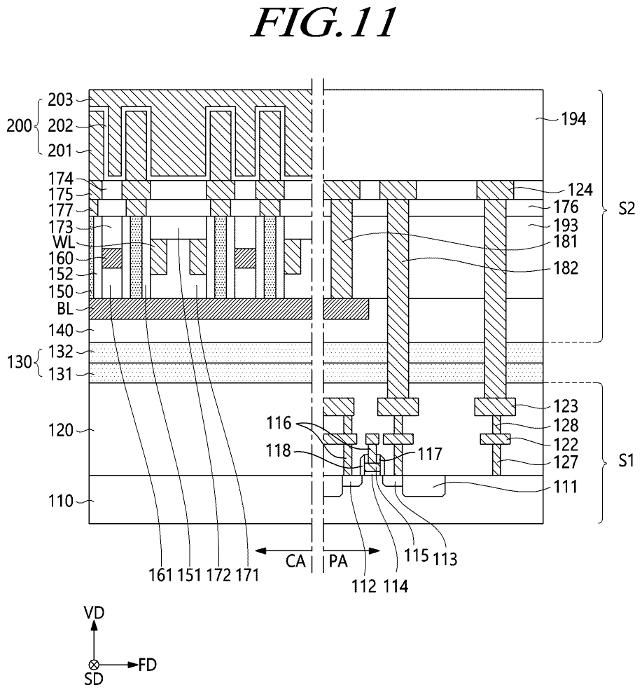

Referring to FIG. 11, a dielectric layer 202 may be formed on the lower electrode 201 and the fourth insulation pattern 174. In an embodiment, the dielectric layer 202 may be conformally formed on the side surface and the upper surface of the lower electrode 201. The dielectric layer 202 covers the side surface and the upper surface of the lower electrode 201, and the upper surface of the fourth insulation pattern 174. The upper electrode 203 may be formed on the dielectric layer 202.

Referring back to FIG. 1, a fifth insulation layer 195 may be formed on the upper electrode 203 and the fourth insulation layer 194. After the fifth insulation layer 195 is formed, a fifth contact 129 passing through the fifth insulation layer 195 may be formed. The fifth contact 129 contacts the upper surface of the upper electrode 203 and the upper surface of the third line 124. A fourth line 125 and a fifth line 126 are formed on the fifth contact 129.

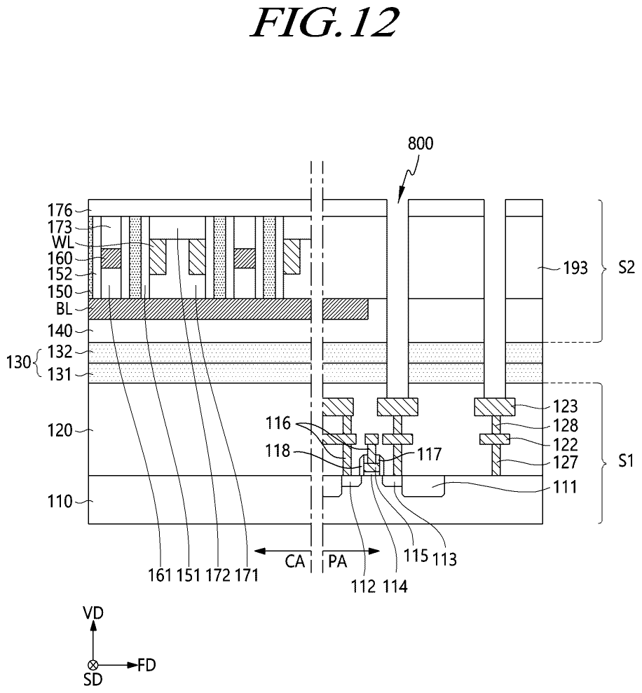

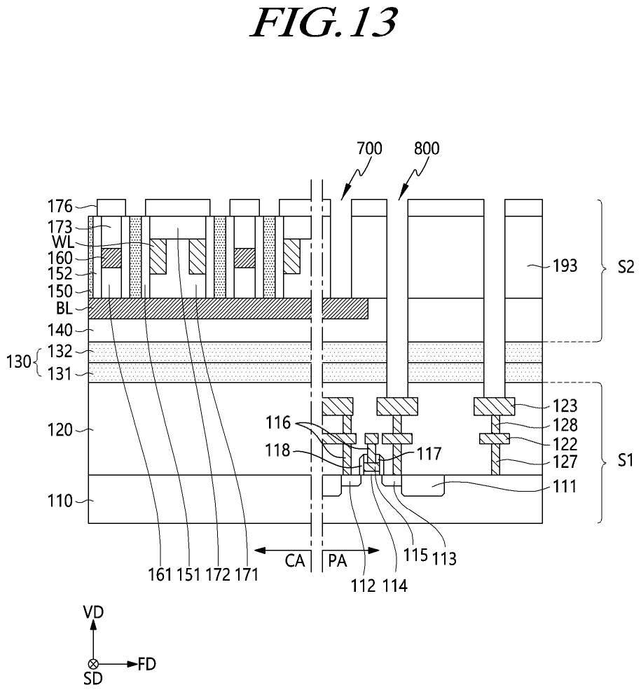

FIGS. 12 and 13 are simplified schematics illustrating another method for manufacturing a memory device according to embodiments of the present disclosure.

The memory device illustrated in FIG. 12 may be formed by the same method as the method for manufacturing the memory device described with reference to FIGS. 2 to 6.

Referring to FIG. 12, a second through hole 800 exposing an upper surface of the second line 123 is formed. The process of forming the second through hole 800 may be the same or substantially the same as the process of forming the second through hole 800 described with reference to FIG. 8.

Referring to FIG. 13, a first through hole 700 is formed exposing the upper surface of the bit line BL. The process of forming the first through hole 700 may be the same or substantially the same as the process of forming the first through hole 700 described with reference to FIG. 7.

The process of forming the second through hole 800 may be separated from the process of forming the first through hole 700. In an embodiment, the process of forming the second through hole 800 may be performed before the process of forming the first through hole 700.

The first through hole 700 and the second through hole 800 may be the same or substantially the same as the first through hole 700 and the second through hole 800, respectively, described with reference to FIG. 8.

Thereafter, a subsequent process of forming the memory device may be performed in the same or substantially the same method as the method of manufacturing the memory device described with reference to FIGS. 9 to 11.

Referring back to FIGS. 7 and 8, the process of forming the first through hole 700 exposing the upper surface of the bit line BL may be separated from the process of forming the second through hole 800 exposing the upper surface of the second line 123. The vertical length L1 of the first through hole 700 is shorter than the vertical length L2 of the second through hole 800.

According to embodiments of the present disclosure, as the process of forming the first through hole 700 is separated from the process of forming the second through hole 800, misalignment between lines may be prevented. This is described below in detail. In a method which performs the process of forming the first through hole 700 simultaneously with the process of forming the second through hole 800, it is difficult to accurately align the area because the width of the bit line BL is very thin, and may result in misalignment. When misalignment occurs, the second insulation layer 140 positioned under the bit line BL may be partially etched and, therefore, the first contact plug 181 may not be properly connected to the bit line BL. Contrast, according to embodiments of the present disclosure, the process of forming the first through hole 700 is separated from the process of forming the second through hole 800. Accordingly, an etching process for forming the first through hole 700 may be performed with respect to the area where the bit line BL is positioned. When the first through hole 700 is formed, the area where exposure is performed may be accurately aligned on the upper surface of the bit line BL. Therefore, misalignment between the first contact plug 181 and the bit line BL in a subsequent process may be prevented.

The above-described embodiments are merely illustrative, and it will be appreciated by one of ordinary skill in the art that various changes may be made thereto without departing from the scope of the present disclosure. Accordingly, the embodiments set forth herein are provided for illustrative purposes, and should not to limit the scope of the present disclosure. It should be appreciated that the scope of the present disclosure is not limited by the illustrated embodiments. Furthermore, the embodiments may be combined to form additional embodiments.

What is claimed is:

1. A method for manufacturing a memory device, the method comprising:
bonding a second semiconductor structure on a first semiconductor structure, wherein the second semiconductor structure includes a second bonding insulation layer and a bit line on the second bonding insulation layer, wherein the first semiconductor structure includes a substrate, lower lines on the substrate, and a first bonding insulation layer on the lower lines;
forming a first hole exposing an upper surface of the bit line in the second semiconductor structure; and
forming a second hole passing through the first bonding insulation layer and the second bonding insulation layer to expose an upper surface of the lower lines.

2. The method of claim 1, wherein in a direction perpendicular to an upper surface of the substrate, a length of the first hole is shorter than a length of the second hole.

3. The method of claim 1, wherein a diameter of the first hole is substantially identical to a diameter of the second hole.

4. The method of claim 1, wherein a diameter of the first hole is narrower than a diameter of the second hole.

5. The method of claim 1, wherein an etching mask for forming the first hole is different from an etching mask for forming the second hole.

6. The method of claim 1, wherein forming the first hole is performed before forming the second hole.

7. The method of claim 1, wherein forming the second hole is performed before forming the first hole.

8. The method of claim 1, further comprising:
forming a first contact plug by filling the first hole with a conductive material;
forming a second contact plug by filling the second hole with a conductive material; and
forming upper lines on the first contact plug and the second contact plug,
wherein an upper surface of the first contact plug and an upper surface of the second contact plug form substantially the same plane.

9. The method of claim 8, wherein one side of the first contact plug is connected to at least one of the upper lines, another side of the first contact plug is connected to the bit line, one side of the second contact plug is connected to at least another one of the upper lines, and another side of the second contact plug is connected to at least one of the lower lines.

10. A method for manufacturing a memory device, the method comprising:
bonding a second semiconductor structure, including a second bonding insulation layer and a bit line on the second bonding insulation layer, on a first semiconductor structure including a substrate, lower lines on the substrate, and a first bonding insulation layer on the lower lines;
forming a first hole exposing an upper surface of the bit line in the second semiconductor structure; and
forming a second hole exposing an upper surface of the lower lines and having a longer length than a length of the first hole in a direction perpendicular to an upper surface of the substrate.

11. The method of claim 10, wherein the second hole passes through the first bonding insulation layer and the second bonding insulation layer.

12. The method of claim 10, wherein a diameter of the first hole is substantially identical to a diameter of the second hole.

13. The method of claim 10, wherein a diameter of the first hole is narrower than a diameter of the second hole.

14. The method of claim 10, wherein an etching mask for forming the first hole is different from an etching mask for forming the second hole.

15. The method of claim 10, wherein forming the first hole is performed before forming the second hole.

16. The method of claim 10, wherein forming the second hole is performed before forming the first hole.

17. The method of claim 10, further comprising:
forming a first contact plug by filling the first hole with a conductive material;
forming a second contact plug by filling the second hole with a conductive material; and
forming upper lines on the first contact plug and the second contact plug,
wherein an upper surface of the first contact plug and an upper surface of the second contact plug form substantially the same plane.

18. The method of claim 10, wherein one side of the first contact plug is connected to at least one of the upper lines, another side of the first contact plug is connected to the bit line, one side of the second contact plug is connected to at least another one of the upper lines, and another side of the second contact plug is connected to at least one of the lower lines.
